(19) United States
(12) Patent Application Publication
(10) Pub. No.: US 2011/0114165 A1
(43) Pub. Date: May 19, 2011

(54) Photoelectric conversion device

(75) Inventor: Yi-Hyun Chang, Suwon-si (KR)

(73) Assignee: Samsung SDI Co., Ltd., Suwon-si (KR)

(21) Appl. No.: 12/659,988

(22) Filed: Mar. 26, 2010

(30) Foreign Application Priority Data
Nov. 17, 2009 (KR) 10-2009-0110920

(51) Int. Cl. H01L 31/04

(52) U.S. Cl. 136/256; 257/E31.001

(57) ABSTRACT

A photoelectric conversion device including a light receiving substrate on which an optical electrode is formed, a counter substrate facing the light receiving substrate, and a semiconductor layer formed on the optical electrode. A counter electrode is formed on the counter substrate. Photosensitive dyes, which is excited by visible light, adhere to the semiconductor layer, and an electrolyte layer is disposed between the semiconductor layer and the counter electrode. Each of the light receiving substrate and the counter substrate includes chamfered units at corners of external surfaces thereof.

### CLAIM OF PRIORITY

This application makes reference to, incorporates the same herein, and claims all benefits accruing under 35 U.S.C. §119 from an application earlier filed in the Korean

Intellectual Property Office on 17 Nov. 2009 and there duly assigned Serial No. 10-2009-0110920.

### BACKGROUND OF THE INVENTION

1. Field of the Invention

One or more embodiments of the present invention relate to a photoelectric conversion device, wherein costs of a chamfering process performed after manufacturing a panel on a mother glass are decreased, productivity of the chamfering process is increased, and defects generated during the chamfering process are reduced.

2. Description of the Related Art

Photoelectric conversion devices convert light energy into electric energy and have been studied as an energy source for replacing fossil fuels, and solar cells using sunlight have come into the spotlight.

Various types of solar cells having various driving principles have been investigated. Silicon or crystalline solar cells have a wafer shape and include a p-n semiconductor junction, but the manufacturing costs thereof are high due to the characteristics of processes for forming and handling semiconductor materials having a high degree of purity.

### SUMMARY OF THE INVENTION

One or more embodiments of the present invention include a photoelectric conversion device, wherein costs of a chamfering process performed after manufacturing a panel on a mother glass are decreased, productivity of the chamfering process is increased, and defects generated during the chamfering process are reduced.

Additional aspects will be set forth in part in the description which follows and, in part, will be apparent from the description, or may be learned by practice of the presented embodiments.

According to one or more embodiments of the present invention, a photoelectric conversion device including a light receiving substrate, an optical electrode formed on an inner surface of the light receiving substrate, a counter substrate having an inner surface facing the light receiving substrate, a counter electrode formed on the inner surface of the counter substrate, a semiconductor layer formed on the optical electrode, photosensitive dyes adhering to the semiconductor layer, and an electrolyte layer disposed between the semiconductor layer and the counter electrode. The photosensitive dyes is capable of being excited by visible light. The light receiving substrate has chamfered units formed at corners of an outer surface of the light receiving substrate. The counter substrate has chamfered units formed at corners of an outer surface of the counter substrate.

The chamfered units may be formed after the light receiving substrate and the counter substrate are attached to each other.

An adhering edge of each of the inner surface of the light receiving substrate and the inner surface of the counter substrate may not be chamfered.

An adhering edge of each of the inner surface of the light receiving substrate and the inner surface of the counter substrate may be chamfered, and a depth of chamfer of the adhering edge may be about 0.5 mm.

Each of the chamfered units of the light receiving substrate may have a chamfer angle in a range of about 20 degrees to about 70 degrees with respect to an adjacent side surface of the light receiving substrate, and the counter substrate may have a chamfer angle in a range of about 20 degrees to about 70 degrees with respect to an adjacent side surface of the counter substrate.

The each of the chamfered units of the light receiving substrate may have a chamfer angle of about 45 degrees with respect to the adjacent side surface of the light receiving substrate, and the each of the chamfered units of the counter substrate may have a chamfer angle of about 45 degrees with respect to the adjacent side surface of the counter substrate.

A depth of chamfer of each of the chamfered units of the light receiving substrate may be about a half of or smaller than a thickness of the light receiving substrate, and a depth of chamfer of each of the chamfered units of the counter substrate may be about a half of or smaller than a thickness of the counter substrate.

The chamfered unit may be formed by using a grinder.

The chamfered unit may be formed by using a torch lamp.

According to one or more embodiments of the present invention, a photoelectric conversion device including a light receiving substrate having chamfered units formed at corners of an outer surface of the light receiving substrate, an optical electrode formed on an inner surface of the light receiving substrate, a counter substrate having an inner surface facing the light receiving substrate, a counter electrode formed on the inner surface of the counter substrate, a semiconductor layer formed on the optical electrode, photosensitive dyes adhering to the semiconductor layer, and an electrolyte layer disposed between the semiconductor layer and the counter electrode. The photosensitive dyes is capable of being excited by visible light. The counter substrate has chamfered units formed at corners of an outer surface of the counter substrate. At least one of the chamfered units of the light receiving substrate is rounded with a predetermined radius of curvature, and at least one of the chamfered units of the counter substrate is rounded with a predetermined radius of curvature.

The chamfered units may be chamfered after the light receiving substrate and the counter substrate are attached to each other.

An adhering edge of each of the inner surface of the light receiving substrate and the inner surface of the counter substrate cohere may not be chamfered.

An adhering edge of the inner surface of the light receiving substrate and the inner surface of the counter substrate may be chamfered, and a depth of chamfer of the adhering edge may be about 0.5 mm.

Each of the chamfered units of the light receiving substrate may have a radius of a curvature in a range of about 0.9 mm to about 1.5 mm, and each of the chamfered units of the counter substrate may have a radius of a curvature in a range of about 0.9 mm to about 1.5 mm.

A depth of chamfer of each of the chamfered units of the light receiving substrate may be about a half of or smaller than a thickness of the light receiving substrate, and a depth of chamfer of each of the chamfered units of the counter substrate may be about a half of or smaller than a thickness of the counter substrate.

The chamfered unit may be formed by using a grinder.

The chamfered unit may be formed by using a torch lamp.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an exploded perspective view of a photoelectric conversion device according to an embodiment of the present invention;

FIG. 2 is a cross-sectional view taken along a line II-II of FIG. 1;

FIG. 3 is a diagram schematically illustrating chamfered corners of projected circumferential areas of substrates of the photoelectric conversion device of FIG. 1, according to an embodiment of the present invention;

FIG. 4 is a diagram schematically illustrating a grinder for chamfering corners of a projected circumferential area of each substrate of the photoelectric conversion device of FIG. 1;

FIG. 5 is a diagram schematically illustrating chamfering of only one corner of each substrate of the photoelectric conversion device of FIG. 1;

FIG. 6 is a diagram schematically illustrating a torch lamp for chamfering a corner of a substrate of the photoelectric conversion device of FIG. 1; and

FIG. 7 is a diagram schematically illustrating rounded corners of projected circumferential areas of substrates of the photoelectric conversion device of FIG. 1, according to an embodiment of the present invention.

### DETAILED DESCRIPTION OF THE INVENTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

Photoelectric conversion devices convert light energy into electric energy and have been studied as an energy source for replacing fossil fuels, and solar cells using sunlight have come into the spotlight.

Various types of solar cells having various operation principles have been investigated. Silicon or crystalline solar cells have a wafer shape and include a p-n semiconductor junction, but the manufacturing costs thereof are high due to the processes for forming and handling semiconductor materials having a high degree of purity.

Dye-sensitized solar cells include a photosensitive dye for generating excited electrons in response to visible light, a semiconductor material for receiving the excited electrons, and an electrolyte for reacting with the excited electrons in an external circuit. Dye-sensitized solar cells have high photoelectric conversion efficiency compared to the silicon solar cells, and thus are expected to be the next generation of solar cells.

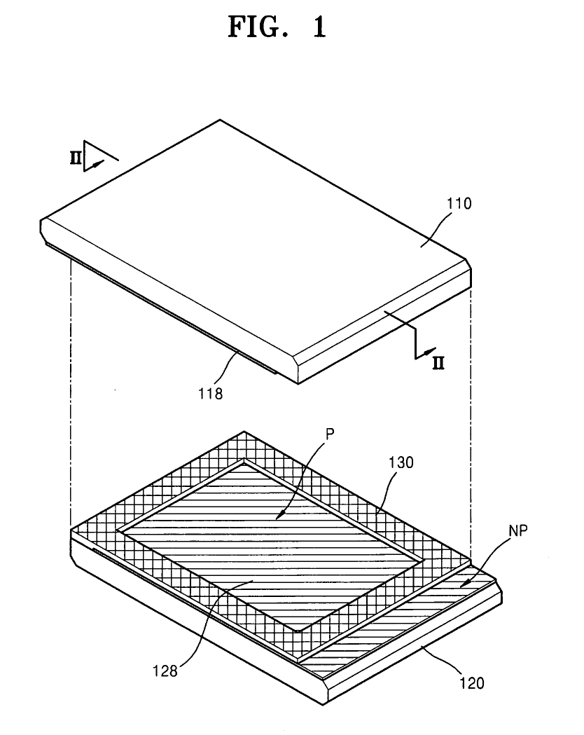

FIG. 1 is an exploded perspective view of a photoelectric conversion device according to an embodiment of the present invention. Referring to FIG. 1, the photoelectric conversion device may be formed by placing a light receiving substrate 110 and a counter substrate 120 to face each other. The receiving substrate 110 includes a first functional layer 118, and the counter substrate 120 includes a second functional layer 128 for performing photoelectric conversion. The light receiving substrate 110 and the counter substrate 120 are sealed by disposing a sealing member 130 along edges of the light receiving substrate 110 and the counter substrate 120. An electrolyte is injected into a space formed between the light receiving substrate 110 and the counter substrate 120 through an electrolyte inlet (not shown). The sealing member 130 prevents the electrolyte from leaking, and separates a photoelectric conversion area P, in which photoelectric conversion occurs, from a peripheral area NP formed outside the photoelectric conversion device.

The functional layers 118 and 128 respectively formed on the light receiving surface substrate 110 and the counter substrate 120 may respectively include a semiconductor layer for generating excited electrons in response to received light, and electrodes for collecting and extracting the generated excited electrons to the outside of the photoelectric conversion device. A part of electrodes respectively included in the functional layers 118 and 128 may be extended to the outside of the sealing member 130 up to the peripheral area NP for electric connection with an external circuit.

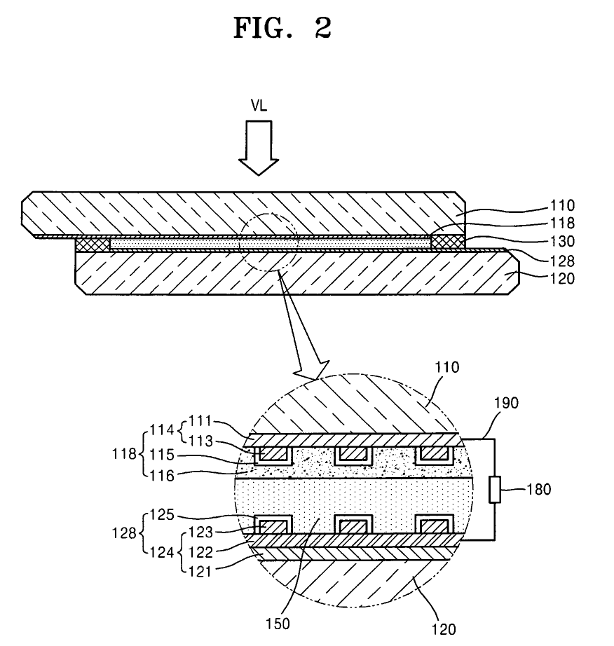

FIG. 2 is a cross-sectional view taken along a line II-II of FIG. 1. Referring to FIG. 2, the light receiving substrate 110 and the counter substrate 120 face each other. An optical electrode 114 is formed on an inner surface of the light receiving substrate and a counter electrode is formed on an inner surface of the counter substrate 120. The inner surface of the light receiving substrate 110 faces the inner surface of the counter substrate 120. A semiconductor layer 116 is formed on the optical electrode 114 and an electrolyte 150 is disposed between the semiconductor layer 116 and the counter electrode 124. Photosensitive dyes, which is capable of being excited by visible light (VL), adhere to the semiconductor layer 116. The optical electrode 114 and the semiconductor layer 116 are included in the functional layer 118 of the light receiving substrate 110, and the counter electrode 124 is included in the functional layer 128 of the counter substrate 120.

The light receiving substrate 110 and the counter substrate 120 are attached to each other with a gap formed therebetween by using the sealing member 130, and the electrolyte 150 may be filled inside the gap between the light receiving surface substrate 110 and the counter substrate 120. The sealing member 130 is formed around the electrolyte 150 so as to prevent the electrolyte 150 from leaking.

The optical electrode 114 and the counter electrode 124 are connected to each other via a conducting wire 190 and an external circuit 180. If a plurality of photoelectric conversion devices are connected to each other in series or in parallel to form a module, the optical electrodes 114 and the counter electrodes 124 may be connected to each other in series or in parallel, and opposite ends thereof may be connected to the external circuit 180.

The light receiving substrate 110 may be formed of a transparent material, such as a material having high light transmittance. For example, the light receiving substrate 110 may be a glass substrate or a resin film. The resin film is generally flexible, and thus is suitable for use when flexibility of the photoelectric conversion device is required.

The optical electrode 114 may include a first transparent conductive layer 111 and a first grid pattern 113 formed on the first transparent conductive layer 111. The transparent conductive layer 111 is formed of a material having both transparency and electric conductivity, for example, a transparent conducting oxide (TCO) such as indium tin oxide (ITO), fluorine-doped tin oxide (FTO), or antimony tin oxide (ATO). The grid pattern 113 is used to reduce the electrical resistance of the optical electrode 114, and operates as a wire for providing a low resistance current path by collecting the generated excited electrons according to a photoelectric conversion effect. For example, the grid pattern 113 may be formed of a metal having excellent electric conductivity, such as gold (Ag), silver (Au), or aluminum (Al), and may be patterned in a stripe form.

The optical electrode 114 may operate as a cathode of the photoelectric conversion device, and may have a high aperture ratio. The incident visible light (VL) to the optical electrode 114 operates as an excitation source of the photosensitive dyes adhering to the semiconductor layer 116, and thus a photoelectric conversion efficiency may be increased by transmitting as much as possible VL.

A protective layer 115 may be formed on an external surface of the grid pattern 113. The protective layer 115 prevents the optical electrode 114 from being damaged, for example, prevents the grid pattern 113 from corroding due to the contact with the electrolyte 150. The protective layer 115 may be formed of a material that does not react with the electrolyte 150, for example, a hardened resin material.

The semiconductor layer 116 may be formed of a general semiconductor material, for example, an oxide of a metal, such as cadmium (Cd), zinc (Zn), indium (In), plumbum (Pb), molybdenum (Mo), tungsten (W), stibium (Sb), titanium (Ti), Ag, manganese (Mn), tin (Sn), zirconium (Zr), strontium (Sr), gallium (Ga), silicon (Si), or a chromium (Cr). The semiconductor layer 116 may have high photoelectric conversion efficiency. Also, the semiconductor layer 116 may be formed by coating the light receiving substrate 110 with a paste, in which semiconductor particles having a particle diameter in the range of about 5 nm to about 1000 nm are distributed, and then performing a heating process or pressurizing process on the light receiving substrate 110.

The photosensitive dyes adhering to the semiconductor layer 116 absorb the incident VL through the light receiving surface substrate 110, and electrons of the photosensitive dyes are excited from a ground state. The excited electrons are transferred to a conduction band of the semiconductor layer 116 by an electric bond between the photosensitive dyes and the semiconductor layer 116, reach the optical electrode 114 through the semiconductor layer 116, and then form a driving current that drives the external circuit 180 by being extracted outside the photoelectric conversion device through the optical electrode 114.

For example, the photosensitive dyes adhering to the semiconductor layer 116 are formed of molecules that absorb the VL, and quickly induce the excited electrons to move to the semiconductor layer 116. The photosensitive dyes may be in a liquefied state, a gel state (half solid state), or a solid state. For example, the photosensitive dyes adhering to the semiconductor layer 116 may be ruthenium-based photosensitive dyes. The semiconductor layer 116, to which the photosensitive dyes adheres, may be obtained by impregnating the light receiving substrate 110, on which the semiconductor layer 116 is formed, in a solution including photosensitive dyes.

The electrolyte 150 may be a Redox electrolyte including a pair of an oxidized material and a reduced material, and may be in a solid state, a gel state, or a liquid state.

Meanwhile, the counter substrate 120 facing the light receiving substrate 110 may not be transparent, but may be formed of a transparent material so that the photoelectric conversion device receives the VL from both sides so as to increase the photoelectric conversion efficiency, and may be formed of the same material as the light receiving substrate 110. In particular, when the photoelectric conversion device is used as a building integrated photovoltaic (BIPV) device installed in a structure such as a window frame, both sides of the photoelectric conversion device may be transparent so as not to block the VL transmitted into the room.

The counter electrode 124 may include a second transparent conductive layer 121 and a catalyst layer 122 formed on the second transparent conductive layer 121. The transparent conductive layer 121 is formed of a material that is both transparent and electrically conductive, for example, a TCO, such as ITO, FTO, or ATO. The catalyst layer 122 is formed of a material having a reduction catalyst function for providing electrons to the electrolyte 150, for example, a metal, such as platinum (Pt), Ag, Au, copper (Cu), or Al, a metal oxide, such as a tin oxide, or a carbon-based material, such as graphite.

The counter electrode 124 operates as an anode of the photoelectric conversion device, and performs functions of a reduction catalyst for providing electrons to the electrolyte 150. The electrons of the photosensitive dyes adhering to the semiconductor layer 116 are excited by absorbing the VL, and the excited electrons are extracted outside the photoelectric conversion device through the optical electrode 114. Meanwhile, the photosensitive dyes that lost electrons are revivified by collecting electrons generated by oxidizing the electrolyte 150, and the oxidized electrolyte 150 is reduced by the electrons that reached the counter electrode 124 through the external circuit 180. Thus, the operation of the photoelectric conversion device is completed.

The counter electrode 124 may include a second grid pattern 123 formed on the catalyst layer 122. The second grid pattern 123 is used to reduce the electrical resistance of the counter electrode 124, and operates as a wire for providing a low resistance current path by collecting the generated excited electrons according to a photoelectric conversion effect. For example, the grid pattern 123 may be formed of a metal having excellent electric conductivity, such as gold (Ag), silver (Au), or aluminum (Al), and may be patterned in a stripe form. A second protective layer 125 may be formed on an external surface of the grid pattern 123. The second protective layer 125 prevents the counter electrode 124 from being damaged, for example, prevents the grid pattern 123 from corroding due to the contact with the electrolyte 150. The second protective layer 125 may be formed of a material that does not react with the electrolyte 150, for example, a hardened resin material.

FIG. 3 is a diagram schematically illustrating chamfered corners (or edges) of projected circumferential areas of substrates of the photoelectric conversion device of FIG. 1, according to an embodiment of the present invention. Referring to FIG. 3, the light receiving substrate 110 has a first protruding portion E1 that does not face the counter substrate 120. The first protruding portion E1 is an edge portion of the light receiving substrate 110. The counter substrate 120 also has a second protruding portion E2 that does not face the light receiving substrate 110. The second protruding portion E2 is an edge portion of the counter substrate 120. Edges of outer and inner surfaces of the protruding portion E1 are chamfered to form chamfered units C1 and C3, respectively. An opposite edge of the outer surface of the light receiving substrate 110, which is an opposite side of the protruding portion E1, is chamfered to form a chamfered unit C2. The chamfered unit C1 and C2 are formed on the outer surface of the light receiving substrate 110, and the chamfered unit C3 is formed on the inner surface of the light receiving substrate 110. Chamfered units C4 and C5 are formed on the second protruding portion E2, and a chamfered unit C6 is formed at an edge of the outer surface of the counter substrate 120, which is an opposite side of the protruding portion E2. The chamfered unit C5 and C6 are formed on the outer surface of the counter substrate 120, and the chamfered unit C4 is formed on the inner surface of the counter substrate 120. The chamfered units C1, C2 and C3 can be referred to as first, second and third chamfered units, respectively, and the chamfered units C4, C5 and C6 can be referred to as fourth, fifth and sixth chamfered units, respectively.

An overlapping region 300 is a region formed between the light receiving substrate 110 and the counter substrate 120. A first adhering edge A1 is an edge of the inner surface of the light receiving substrate 110, which is an opposite side of the first protruding portion E1. A second adhering edge A2 is an edge of the inner surface of the counter substrate 120, which is an opposite side of the second protruding portion E2. Therefore, the first and second adhering edges A1 and A2 represent two opposite edges of the overlapping region 300. The first and second adhering edges A1 and A2 may not be chamfered or may be slightly chamfered. If the adhering edges A1 and A2 are chamfered, a depth of chamfer at each of the adhering edges A1 and A2 is about 0.5 mm. A depth of chamfer at each of the chamfered units C1 through C6 is no less than 0.5 mm. Therefore, the depth of chamfer of the chamfer units C1 through C6 may be equal to or greater than the depth of chamfer at the adhering edges A1 and A2. The depth of chamfer D is illustrated in FIG. 3. The meaning of the depth of chamfer D is a size of a chamfered portion measured on the inner or outer surface of a substrate.

Generally, the light receiving substrate 110 and the counter substrate 120 are attached to each other after chamfering the corners thereof. However, according to the current embodiment of the present invention, the light receiving substrate 110 and the counter substrate 120 are first attached to each other, and then a chamfering process is performed. Accordingly, the manufacturing cost is reduced and productivity is increased.

The chamfered units C1 through C6 may form a chamfer angle with respect to an adjacent side surface. For example, the chamfer angle may be in the range between about 20° (degrees) to about 70° (degrees), for example, 45° (degrees). The chamfer angle θ is defined as an acute angle between a surface of a chamfered unit and an adjacent side surface of a substrate as shown in FIG. 3. Herein, the side surface is a surface that is disposed perpendicular to the inner and outer surfaces of the substrate.

In another embodiment, a depth of chamfer of each of the chamfered units C1, C2 and C3 of the light receiving substrate 110 is about a half of or smaller than a thickness of the light receiving substrate. A depth of chamfer of each of the chamfered units C4, C5 and C6 of the counter substrate 120 is about a half of or smaller than a thickness of the counter substrate. Herein, the thickness of a substrate (the light receiving substrate 110 or the counter substrate 120) is defined as a size of the substrate along the side surfaces of the substrate. FIG. 3 illustrate, for example, the thickness T of the light receiving substrate 110.

The chamfered units C1 through C6 may be formed by grinding via using a grinder or by burning using a torch lamp.

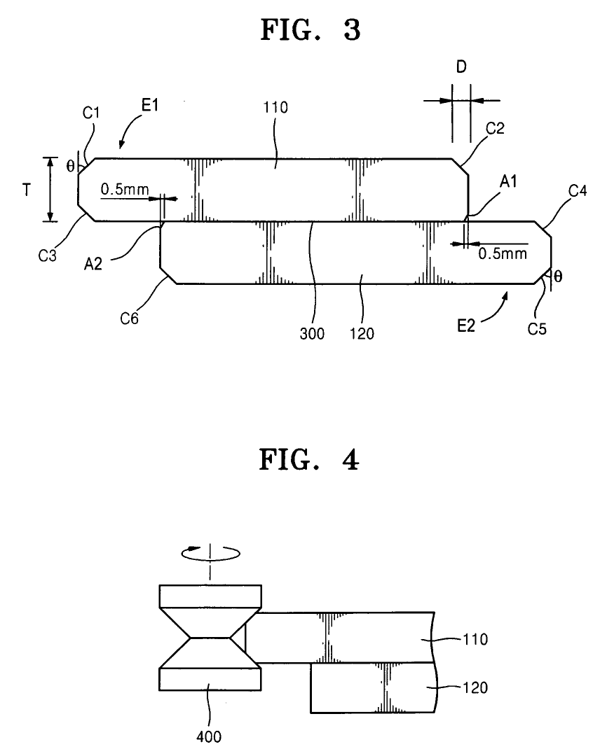

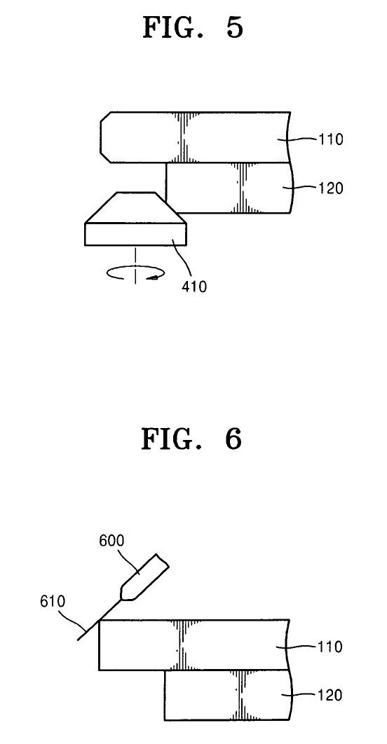

A process of forming a chamfered unit by using a grinder will now be described with reference to FIGS. 4 and 5.

The photoelectric conversion device to be chamfered is placed on the bed of a grinding machine as shown in FIGS. 4 and 5, while the light receiving substrate 110 and the counter substrate 120 are attached to each other. In order to chamfer corners of projected circumferential areas of the light receiving substrate 110 and the counter substrate 120, a grinder 400 having a double truncated cone shape as shown in FIG. 4 is used. A chamfer angle of each chamfered unit may be adjusted according to an angle of the grinder 400. Accordingly, the chamfered units C1 and C3, and C4 and C5 of FIG. 3 are simultaneously formed.

Then, the chamfered units C2 and C6 of FIG. 3 are formed by using a grinder 410 having a truncated cone shape as shown in FIG. 5. A chamfer angle of each chamfered unit may be adjusted according to an angle of the grinder 410.

FIG. 6 is a diagram schematically illustrating a torch lamp 600 for chamfering corners of projected circumferential areas of the light receiving substrate 110 and the counter substrate 120.

As shown in FIG. 6, by disposing the torch lamp 600 at a suitable inclination angle, a needle-shaped flame 610 from the torch lamp 600 may chamfer the corner of each the light receiving substrate 110 and the counter substrate 120.

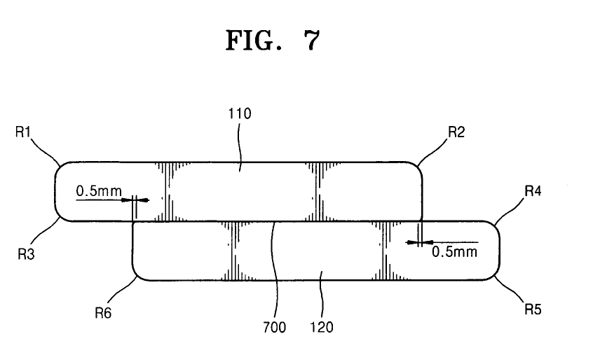

FIG. 7 is a diagram schematically illustrating rounded corners of projected circumferential areas of the light receiving substrate 110 and the counter substrate 120 of the photoelectric conversion device of FIG. 1, according to an embodiment of the present invention. Chamfered units R1 through R6 formed at corners of the light receiving substrate 110 and the counter substrate 120 may be rounded to have a chamfer radius of a curvature R. The radius of the curvature R may be in the range of about 0.9 to about 1.5 mm. Edges of overlapping region 700, corresponding to the adhering edges A1 and A2, may not be chamfered or may be slightly chamfered. If the adhering edges A1 and A2 are chamfered, a depth of chamfer of each of the adhering edges A1 and A2 may be about 0.5 mm. Other descriptions regarding FIG. 7 are identical to those regarding FIG. 3, and thus details thereof are not repeated.

As described above, according to the one or more of the above embodiments of the present invention, a chamfering process may be partially omitted, and thus the manufacturing costs are decreased and productivity is increased. Also, by performing the chamfering process after adhering the substrates, defects due to foreign substances generated during the chamfering process may be reduced.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A photoelectric conversion device comprising:
a light receiving substrate having chamfered units formed at corners of an outer surface of the light receiving substrate;
an optical electrode formed on an inner surface of the light receiving substrate;
a counter substrate having an inner surface facing the light receiving substrate, the counter substrate having chamfered units formed at corners of an outer surface of the counter substrate;
a counter electrode formed on the inner surface of the counter substrate;
a semiconductor layer formed on the optical electrode;
photosensitive dyes adhering to the semiconductor layer, the photosensitive dyes being capable of being excited by visible light; and
an electrolyte layer disposed between the semiconductor layer and the counter electrode.

2. The photoelectric conversion device of claim 1, wherein the chamfered units are formed after the light receiving substrate and the counter substrate are attached to each other.

3. The photoelectric conversion device of claim 1, wherein an adhering edge of each of the inner surface of the light receiving substrate and the inner surface of the counter substrate is not chamfered.

4. The photoelectric conversion device of claim 1, wherein an adhering edge of each of the inner surface of the light receiving substrate and the inner surface of the counter substrate is chamfered, and a depth of chamfer of the adhering edge is about 0.5 mm.

5. The photoelectric conversion device of claim 1, wherein each of the chamfered units of the light receiving substrate has a chamfer angle in a range of about 20 degrees to about 70 degrees with respect to an adjacent side surface of the light receiving substrate, and the counter substrate has a chamfer angle in a range of about 20 degrees to about 70 degrees with respect to an adjacent side surface of the counter substrate.

6. The photoelectric conversion device of claim 5, wherein the each of the chamfered units of the light receiving substrate has a chamfer angle of about 45 degrees with respect to the adjacent side surface of the light receiving substrate, and the each of the chamfered units of the counter substrate has a chamfer angle of about 45 degrees with respect to the adjacent side surface of the counter substrate.

7. The photoelectric conversion device of claim 1, wherein a depth of chamfer of each of the chamfered units of the light receiving substrate is about a half of or smaller than a thickness of the light receiving substrate, and a depth of chamfer of each of the chamfered units of the counter substrate is about a half of or smaller than a thickness of the counter substrate.

8. The photoelectric conversion device of claim 1, wherein the chamfered unit is formed by using a grinder.

9. The photoelectric conversion device of claim 1, wherein the chamfered unit is formed by using a torch lamp.

10. A photoelectric conversion device comprising:
a light receiving substrate having chamfered units formed at corners of an outer surface of the light receiving substrate, at least one of the chamfered units of the light receiving substrate being rounded with a predetermined radius of curvature;
an optical electrode formed on an inner surface of the light receiving substrate;
a counter substrate having an inner surface facing the light receiving substrate, the counter substrate having chamfered units formed at corners of an outer surface of the counter substrate, at least one of the chamfered units of the counter substrate being rounded with a predetermined radius of curvature;
a counter electrode formed on the inner surface of the counter substrate;
a semiconductor layer formed on the optical electrode;
photosensitive dyes adhering to the semiconductor layer, the photosensitive dyes being capable of being excited by visible light; and
an electrolyte layer disposed between the semiconductor layer and the counter electrode.

11. The photoelectric conversion device of claim 10, wherein the chamfered units are chamfered after the light receiving substrate and the counter substrate are attached to each other.

12. The photoelectric conversion device of claim 10, wherein an adhering edge of each of the inner surface of the light receiving substrate and the inner surface of the counter substrate cohere is not chamfered.

13. The photoelectric conversion device of claim 10, wherein an adhering edge of each of the inner surface of the light receiving substrate and the inner surface of the counter substrate is chamfered, and a depth of chamfer of the adhering edge is about 0.5 mm.

14. The photoelectric conversion device of claim 10, wherein each of the chamfered units of the light receiving substrate has a radius of a curvature in a range of about 0.9 mm to about 1.5 mm, and each of the chamfered units of the counter substrate has a radius of a curvature in a range of about 0.9 mm to about 1.5 mm.

15. The photoelectric conversion device of claim 10, wherein a depth of chamfer of each of the chamfered units of the light receiving substrate is about a half of or smaller than a thickness of the light receiving substrate, and a depth of chamfer of each of the chamfered units of the counter substrate is about a half of or smaller than a thickness of the counter substrate.

16. The photoelectric conversion device of claim 10, wherein the chamfered unit is formed by using a grinder.

17. The photoelectric conversion device of claim 10, wherein the chamfered unit is formed by using a torch lamp.
